(19) United States
(12) Patent Application Publication
(10) Pub. No.: US 2011/0104843 A1
(43) Pub. Date: May 5, 2011

(54) METHOD OF REDUCING DEGRADATION OF MULTI QUANTUM WELL (MQW) LIGHT EMITTING DIODES

(75) Inventor: Sung Won Jun, Cupertino, CA (US)

(73) Assignee: Applied Materials, Inc., Santa Clara, CA (US)

(21) Appl. No.: 12/842,908

(22) Filed: Jul. 23, 2010

Related U.S. Application Data
(60) Provisional application No. 61/230,671, filed on Jul. 31, 2009.

(51) Int. Cl. H01L 33/06

(52) U.S. Cl. 438/45; 438/47; 257/E33.01; 257/E33.034

(57) ABSTRACT

A method of fabricating a light emitting diode. According to embodiments of the present invention an active region comprising a plurality of gallium nitride (GaN) barrier layers and a plurality of indium gallium nitride (InGan) quantum well layers are formed over a substrate. A p-type gallium nitride layer is formed above the active region by a hydride vapor phase epitaxy (HVPE) at a high deposition rate.

This application claims the benefit of and priority to Provisional Application Ser. No. 61/230,671, filed Jul. 31, 2009 which is hereby incorporated by reference.

### BACKGROUND OF THE INVENTION

1. Field of the Invention

Embodiments of the present invention relate to a method of reducing of the degradation of multiple quantum well in light emitting diodes by utilizing a fast growth rate of chlorine based hydride vapor phase epitaxy for upper p-type gallium nitride layers.

2. Discussion of Related Art

Light emitting diodes (LEDs) are the ultimate light source in lighting technology. The LED technology has flourished for the past few decades. High efficiency, reliability, rugged construction, low power consumption, and durability are among the key factors for the rapid development of the solid-state lighting based on high-brightness visible LEDs. Conventional light sources, such as filament light bulbs or fluorescent lamps depend on either incandescence or discharge in gases. These two processes are accompanied by large energy losses, which are attributed to high temperatures and large Stokes shift characteristics. On the other hand, semiconductors allow an efficient way of light generation. LEDs made of semiconductor materials have the potential of converting electricity to light with near unity efficiency. An example of a typical gallium nitride (GaN) based light emitting diodes (LEDs) is illustrated in FIG. 1. The LED structure includes a substrate 102 having an active region 104 sandwiched between a n-type contact layer 106, such as a silicon doped gallium nitride (Si—GaN) layer and a p-type contact layer 108, such as a magnesium doped gallium nitride (Mg—GaN) layer. The active region generally comprises one or more indium gallium nitride (InGaN) or aluminum gallium nitride (AlGaN) quantum well layers 120 and a plurality of barrier layers 122, such as gallium nitride (GaN) layers, to create a multi-quantum well (MQW) device. LED structure 100 generally includes a magnesium doped electron blocking layer (EBL) 110, such as an Mg—AlGaN layer, to effectively confine the radiative recombination within the active region.

The p-type contact layer 108 and the p-type electron blocking layer 110 are typically formed utilizing a metal organic chemical vapor deposition (MOCVD) process. In order to deposit a high quality single crystalline p-type GaN film by MOCVD, high deposition temperatures, such as greater than 1000° C., and low deposition rates are required. Unfortunately, the exposure of the quantum wells and barrier layers to high temperatures for extended periods of time result in the interdiffusion of indium (In) and gallium (Ga) in the quantum well and barrier layers resulting in the formation of an indium (In) rich indium gallium nitride InGaN precipitates which retard the optical quality of the MQW active layers.

### SUMMARY

A method of fabricating a light emitting diode. According to embodiments of the present invention an active region comprising a plurality of gallium nitride (GaN) barrier layers and a plurality of indium gallium nitride (InGan) quantum well layers are formed over a substrate. A p-type gallium nitride layer is formed above the active region by a hydride vapor phase epitaxy (HVPE) at a high deposition rate.

### BRIEF DESCRIPTION OF THE DRAWINGS

FIG. 1 is an illustration of a conventional gallium nitride (GaN) based LED.

FIG. 2A is an illustration of a partially fabricated GaN based LED.

FIG. 2B is an illustration of a gallium nitride LED fabricated in accordance with an embodiment of the present invention.

FIG. 3 is an isometric view illustrating a processing system according to an embodiment of the invention.

FIG. 4 is a plan view of the processing system illustrated in FIG. 3.

FIG. 5 is an isometric view illustrating a load station and loadlock chamber according to an embodiment of the invention.

FIG. 6 is a schematic view of a loadlock chamber according to an embodiment of the invention.

FIG. 7 is an isometric view of a carrier plate according to an embodiment of the invention.

FIG. 8 is a schematic view of a batch loadlock chamber according to an embodiment of the invention.

FIG. 9 is an isometric view of a work platform according to an embodiment of the invention.

FIG. 10 is a plan view of a transfer chamber according to an embodiment of the invention.

FIG. 11 is a schematic cross-sectional view of a HVPE chamber according to an embodiment of the invention.

FIG. 12 is a schematic cross-sectional view of an MOCVD chamber according to an embodiment of the invention.

FIG. 13 is a schematic view illustrating another embodiment of a processing system for fabricating compound nitride semiconductor devices.

FIG. 14 is a schematic view illustrating yet another embodiment of a processing system for fabricating compound nitride semiconductor devices.

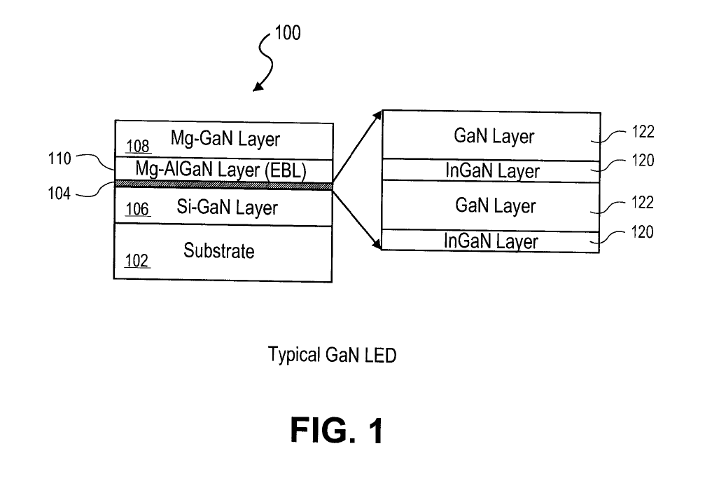

### DETAILED DESCRIPTION

The present invention is a method of forming a high quality light emitting diode (LED) having multiple quantum wells (MQW) active layers. The present invention has been described with respect to specific details in order to provide a thorough understanding of the invention. One of ordinary skill in the art will appreciate that the invention can be practiced without these specific details. In other instances, well known semiconductor processes and equipment have not been described in specific detail in order to not unnecessarily obscure the present invention.

The present invention is a method of forming a high quality light emitting diode (LED) having multiple quantum wells (MQW) active layers. According to an embodiment of the present invention, after the formation of the active region of the light emitting diode including a plurality of quantum well layers, such as indium gallium nitride (InGaN) layers and a plurality of barrier layers, such as gallium nitride (GaN) layers, a p-type contact layers, such as a magnesium doped gallium nitride layer (Mg—GaN), is formed on the active region by a chlorine based hydride vapor phase epitaxial (HVPE) deposition process. The use of an HVPE process enables the p-type GaN film to formed at a high growth rate, such as greater than 25 μm/hr, and ideally greater than 100 μm/hr so that the underlying quantum well/barrier layers are exposed to high temperatures for a much shorter time. By decreasing the amount of time that the active region is exposed to high temperatures prevents or reduces indium (In) and gallium (Ga) interdiffusion and therefore the formation of indium (In) rich which indium gallium nitride (InGaN) precipitates which retard the optical quality of the MQW active layers. Additionally, in embodiments of the present invention, a p-type GaN layer is formed by HVPE at a relatively low temperature such as less than or equal to 900 C. In embodiments of the present invention, the upper p-type GaN contact layer is grown by HVPE at a sufficiently high growth rate and/or at sufficiently low deposition temperature to reduce the degree of degradation of the active MQW and thereby increase the internal quantum efficiency (IQE) to enable the formation of high brightness LEDs.

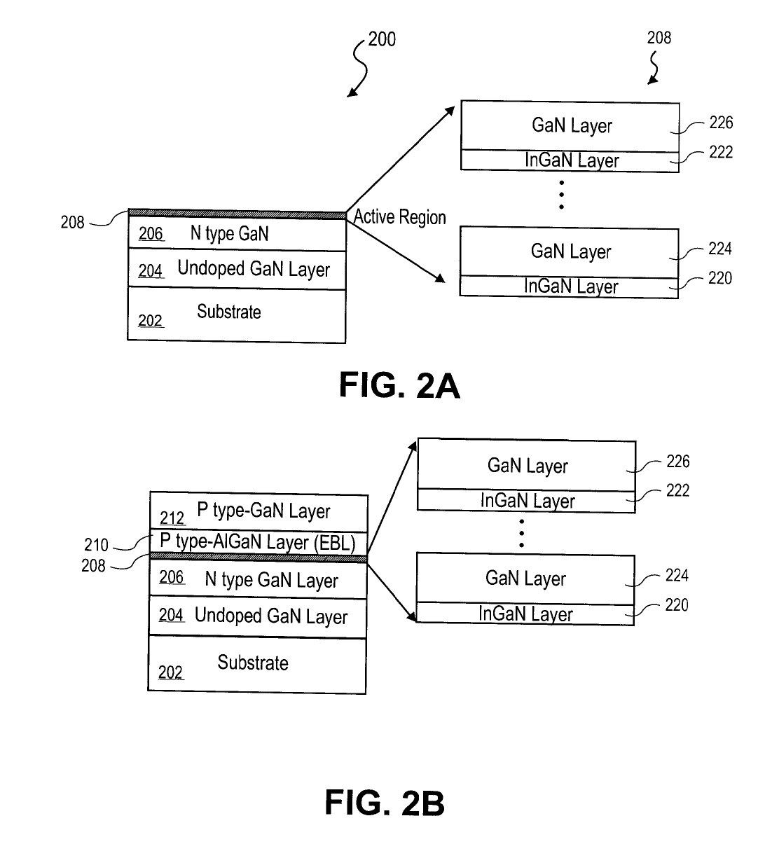

FIG. 2A is an illustration of a partially fabricated gallium nitride (GaN) based light emitting diode (LED) in accordance with an embodiment of the present invention. The partially fabricated LED device includes a bulk substrate 202. Bulk substrate may be any suitable substrate, such as but not limited to a sapphire (Al₂O₃) substrate, a silicon substrate, a silicon carbide (SiC) substrate, a silicon (Si) substrate, a zinc oxide (ZnO) substrate, a magnesium oxide (MgO) substrate, a gallium nitride (GaN) substrate, a lithium aluminum oxide (LiAlO₂) substrate and a lithium gallium oxide (LiGaO₂) substrate. Additionally substrate 202 may be a planar substrate or may have patterned features therein.

An undoped gallium nitride (GaN) single crystalline or crystalline film 204 is formed on substrate 202. Undoped gallium nitride film 204 can be formed to any suitable thickness. In an embodiment of the present invention, an optional buffer layer 203 may be formed between undoped gallium nitride layer 204 and substrate 202. Buffer layer 203 generally will have a lattice constant between that of undoped gallium nitride layer 204 and substrate 202.

Next, an n-type gallium nitride (GaN) contact layer 206 is formed on the undoped gallium nitride layer 204. N-type gallium nitride layer can be formed to a thickness between 0.1-4.0 microns and doped to an n-type conductivity between 1×10¹⁸-5×10¹⁹ atoms/cm³. Any suitable n-type dopants, such as but not limited to Si, Ge, Sn, Pb or any suitable Group IV, Group V, or Group VI element may be utilized.

An active region 208 is formed on the n-type gallium nitride contact layer 206. In an embodiment of the present invention, the active region 208 includes at least a first quantum well 220 and a second quantum well 222 and at least a first barrier layer 224 and a second barrier layer 226. In an embodiment of the present invention, the active region 208 includes a first indium gallium nitride (InGaN) quantum well 220 and a second indium gallium nitride (InGaN) quantum well 222 and a first gallium nitride (GaN) barrier 224 and a second gallium nitride (GaN) barrier 226. In an embodiment of the present invention, the active region 208 includes between 10-20 stacks of barrier layers and wells wherein each stack includes a quantum well layer between 1-5 nanometers thick and a barrier layer between 1-30 nanometers thick.

In an embodiment of the present invention, the quantum well layers and barrier layers of the active region 208 are formed by metal organic chemical vapor deposition (MOCVD) utilizing a relatively low deposition temperature, such as between 750-850° C. to provide a clean sharp interface between the barrier layers and the quantum wells.

A gallium nitride (GaN) film may be formed by MOCVD by providing a metal organic source of gallium, such as trimethylgallium (TMGa) into a chamber along with the nitrogen source, such as ammonia (NH₃) in a chamber containing a substrate. A carrier gas, such as N₂ may be utilized. The substrate may be heated to a temperature between 700-850° C. which causes the source gases to react and to form a gallium nitride (GaN) film on the substrate. The chamber can be maintained at a pressure between 100 torr to atmospheric pressure while depositing the gallium nitride film.

An indium gallium nitride (InGaN) film may be formed by MOCVD by providing a metal organic source of indium, such as trimethylindium (TMIn) and an organic source of gallium, such as trimethylgallium (TMGa) into a chamber along with a nitrogen source, such as ammonia (NH₃) in a chamber containing a substrate. A carrier gas, such as N₂ may be utilized. The substrate may be heated to a growth temperature between 700-850° C. which causes the source gases to react and form an indium gallium nitride (InGaN) film on the substrate. The chamber can be maintained at a pressure between 100 torr to atmospheric pressure while depositing the indium gallium nitride (InGaN) film. In an embodiment of the present invention, the indium gallium nitride film has an atomic formula of In₁Ga₁₋ₓN where 0.05≦x≦0.25. A 20-80% indium atomic ratio in the gas phase with respect to gallium will yield between 5-25% indium in the solid phase.

Next, as shown in FIG. 2B, a p-type single crystalline gallium nitride (GaN) contact layer 212 having a thickness between 200-4000 nanometers is formed above the active region 208. In an embodiment of the present invention, a relatively thin 10-50 nanometers, electron blocking layer (ELB), such as but not limited to a p-type single crystalline aluminum gallium nitride (AlGaN) film having the atomic formula of Al₁Ga₁₋ₓN wherein 0.0≦x≦0.2 is formed between the p-type gallium nitride (GaN) layer the active region 208. The electron blocking layer 210 is provided to help confine the radiative recombination with an active region. In an embodiment of the present invention the p-type gallium nitride (GaN) layer 212 is formed by a chlorine based HVPE deposition technique with a high growth rate of at least 25 μm/hr, and preferably greater than 50 μm/hr, and ideally greater than 100 μm/hr, in order to reduce the amount of time the active 208 is exposed to elevated temperatures, such as temperatures greater than 900° C., which are useful to form high quality single crystalline epitaxially deposited p-type gallium nitride films. It is to be appreciated that higher deposition rates can result in rough surfaces. Accordingly, in an embodiment of the present invention, the highest possible growth rate is used that still enables the formation of a high quality low defect density single crystalline p-type GaN film with a smooth surface. Additionally, in an embodiment of the present invention, the substrate deposition temperature during the HVPE is kept relatively low, such as between 600-900° C., in order to reduce the temperature to which the quantum wells and barrier layers are exposed. In an embodiment of the present invention, the p-type gallium nitride film is formed with a chlorine based HVPE process with a high deposition rate of greater than 25 μm/hr and ideally greater than 100 μm/hr and a low deposition temperature of less than 900° C. so as to reduce the amount interdiffusion of indium (In) and gallium (Ga) and the formation of an indium (In) rich indium gallium nitride (InGaN) precipitate. In this way, a LED device with a high internal quantum efficiency (IQE) for high brightness may be achieved.

Additionally, in embodiments of the present invention, the p-type aluminum gallium nitride electron blocking layer 210 is also formed by a chlorine based HVPE technique with a high deposition rate and low deposition temperature. It is to be appreciated that since the electron blocking layer is significantly thinner than the p-type contact layer 212, it is not as important to form this film with a high growth rate and low deposition temperature and as is the p-type contact layer 212.

The p-type gallium nitride contact layer 212 and the p-type aluminum gallium nitride layer 210 may be doped to a p-type conductivity level between 1×10¹⁷-1×10²⁰ atoms/cm². The p-type dopants can be any element having two valance electrons, such as but not limited to zinc (Zn), magnesium (Mg), lithium (Li), calcium (Ca), Strontium (Sr), Beryllium (Be) and cadmium (Cd). In an specific embodiment the electron barrier layer 210 is a magnesium doped aluminum gallium nitride layer (Mg—AlGaN) and the p-type contact layer is a magnesium doped gallium nitride (Mg—GaN) layer.

A magnesium doped gallium nitride (Mg—GaN) layer can be formed by HYPE by providing a gallium containing precursor, such as gallium chloride (GaCl or GaCl₃), a magnesium containing precursor, such as magnesium chloride (MgCl) and a nitrogen containing precursor, such as ammonia (NH₃) into a chamber and reacting them together near the surface of the substrate to deposit a magnesium doped gallium nitride (Mg—GaN) film. In an embodiment of the present invention, the gallium containing precursor is formed by providing a source of gallium, and flowing over it a halide or halogen gas to form a gaseous gallium containing precursor. In an embodiment of the present invention, HCl is reacted with a liquid gallium source to form gaseous gallium chloride (GaCl). In another embodiment of the present invention, chlorine gas (Cl₂) is reacted with a liquid gallium to form GaCl and GaCl₃. Similarly, a magnesium (Mg) containing precursor can be formed by providing a magnesium source and flowing over it a halide or halogen gas to form a magnesium containing precursor. In an embodiment of the present invention, Cl₂ is reacted with magnesium (Mg) to form magnesium chloride (MgCl). In an embodiment of the present invention, the chamber is maintained at a pressure between 100 torr and 760 torr during deposition. In one embodiment, the chamber is maintained at a pressure of about 450 torr to about 760 torr while depositing the magnesium doped gallium nitride (Mg—GaN) film. In an embodiment of the present invention, the magnesium doped gallium nitride film is formed at a temperature less than 900° C. and ideally the temperature is between 600-900° C. A high quality single crystalline p-type GaN film can be reasonably formed by HVPE at a growth rate between 5 μm/hr and 100 μm/hr.

In an embodiment of the present invention, one or more magnesium doped gallium nitride (Mg—GaN) barrier layers are formed by HVPE using a magnesium gallium (MgGa) eutectic alloy as the source. HCl or chlorine gas (Cl₂) is then reacted with the magnesium gallium (MgGa) eutectic alloy to form gaseous magnesium chloride (MgCl) and gallium chloride (GaCl or GaCl₃).

In an embodiment of the present invention a high deposition rate of greater than or equal to 100 μm/hr may be achieved by providing a high Cl2 flow rate of greater than 150 SCCMs over or equal to the gallium source to form gallium trichloride (GaCl₃) or gallium chloride (GaCl). Additionally, in an embodiment of the present invention, a high GaCl and/or GaCl₃ partial pressure of greater than 100 torr is used to help increase the deposition rate of the p-type gallium nitride film. In an embodiment of the present invention, the temperature of the boat which contains the gallium source is at least 500° C. during deposition to help promote a high deposition rate.

An Mg—AlGaN electron blocking layer can be formed by HVPE in a manner similar to a Mg—GaN layer except that an aluminum (Al) source is also provided.

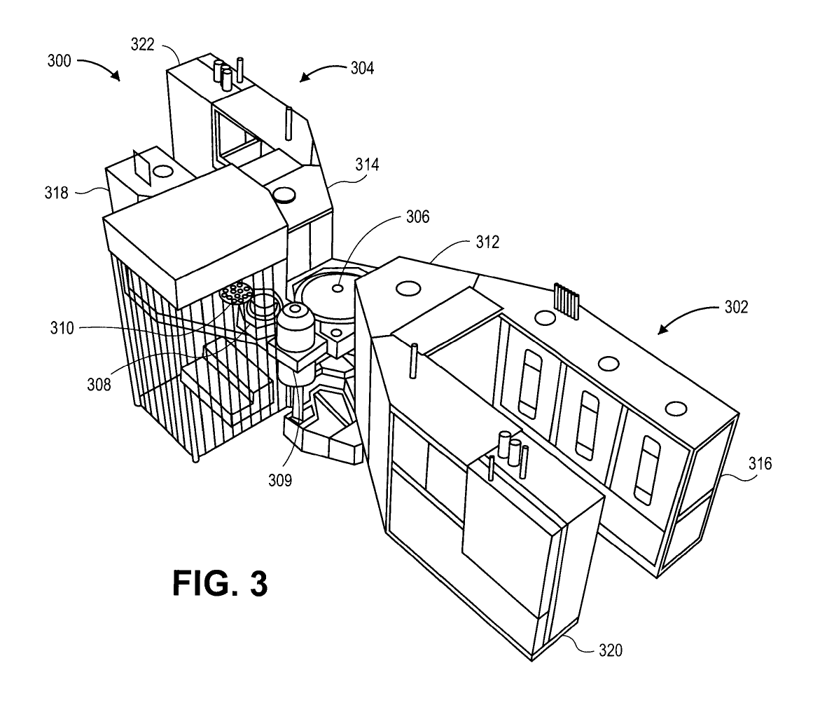

In an embodiment of the present invention, the LED device is fabricated in a cluster tool having one or more MOCVD chambers and one or more HVPE chambers. In this way, the quantum well layers and the barrier layers can be formed by MOCVD in the MOCVD chambers and the p-type gallium nitride blocking layer, if desired, may be fabricated in the HVPE chambers. An example of a cluster tool which may be used to fabricate an LED device in accordance with the present invention is set forth and described with respect to FIGS. 3-14.

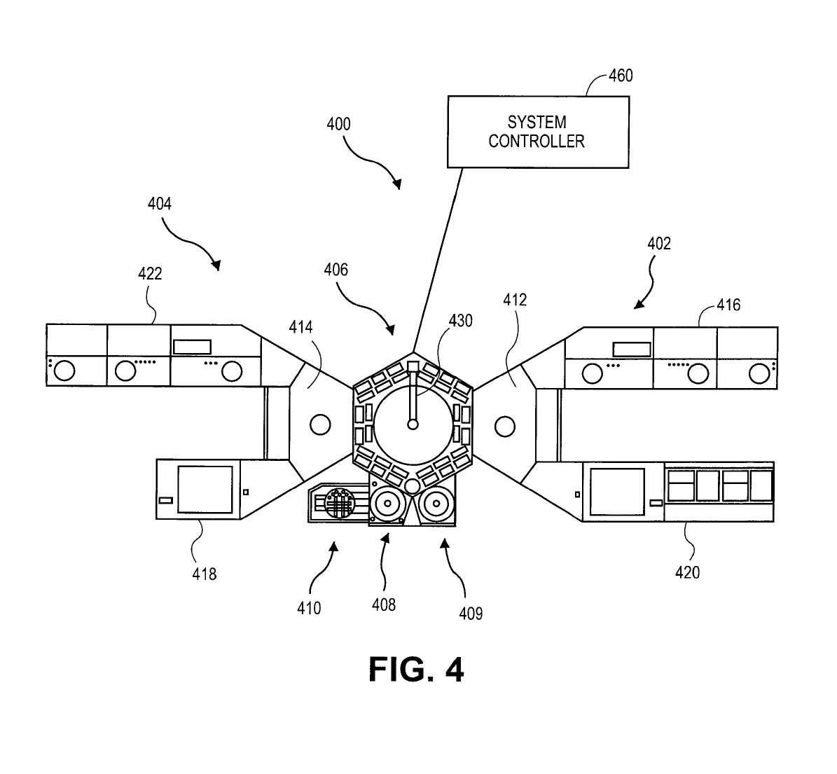

FIG. 3 is an isometric view of one embodiment of a processing system 300 that illustrates a number of aspects of the present invention that may be advantageously used. FIG. 4 illustrates a plan view of one embodiment of a processing system 300 illustrated in FIG. 3. With reference to FIG. 3 and FIG. 4, the processing system 300 comprises a transfer chamber 306 housing a substrate handler, a plurality of processing chambers coupled with the transfer chamber, such as a MOCVD chamber 302 and a HVPE chamber 304, a loadlock chamber 308 coupled with the transfer chamber 306, a batch loadlock chamber 309, for storing substrates, coupled with the transfer chamber 306, and a load station 310, for loading substrates, coupled with the loadlock chamber 308. The transfer chamber 306 comprises a robot assembly 330 operable to pick up and transfer substrates between the loadlock chamber 308, the batch loadlock chamber 309, the MOCVD chamber 302 and the HVPE chamber 304. The movement of the robot assembly 330 may be controlled by a motor drive system (not shown), which may include a servo or stepper motor.

Each processing chamber comprises a chamber body (such as element 312 for the MOCVD chamber 302 and element 314 for the HVPE chamber 304) forming a processing region where a substrate is placed to undergo processing, a chemical delivery module (such as element 316 for the MOCVD chamber 302 and element 318 for the HVPE chamber 304) from which gas precursors are delivered to the chamber body, and an electrical module (such as element 320 for the MOCVD chamber 302 and element 322 for the HVPE chamber 304) that includes the electrical system for each processing chamber of the processing system 300. The MOCVD chamber 302 is adapted to perform CVD processes in which metalorganic elements react with metal hydride elements to form thin layers of compound nitride semiconductor materials. The HVPE chamber 304 is adapted to perform HVPE processes in which gaseous metal halides are used to epitaxially grow thick layers of compound nitride semiconductor materials on heated substrates. In alternate embodiments, one or more additional chambers may 370 be coupled with the transfer chamber 306. These additional chambers may include, for example, anneal chambers, clean chambers for cleaning carrier plates, or substrate removal chambers. The structure of the processing system permits substrate transfers to occur in a defined ambient environment, including under vacuum, in the presence of a selected gas, under defined temperature conditions, and the like.

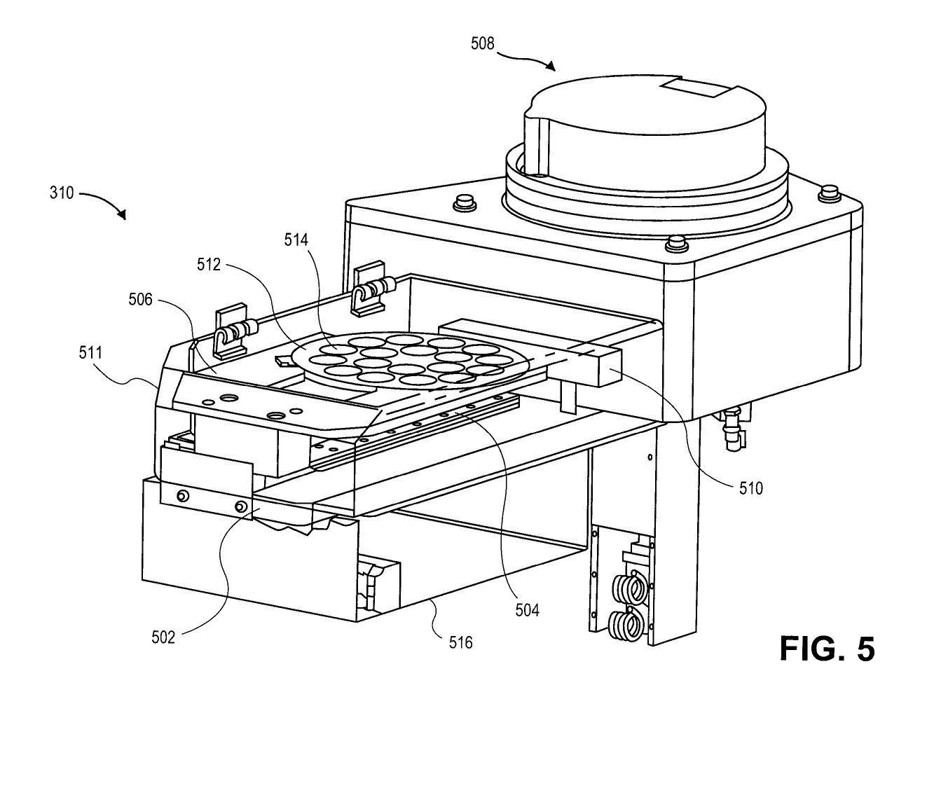

FIG. 5 is an isometric view illustrating a load station 310 and a loadlock chamber 308 according to an embodiment of the invention. The load station 310 is configured as an atmospheric interface to allow an operator to load a plurality of substrates for processing into the confined environment of the loadlock chamber 308, and unload a plurality of processed substrates from the loadlock chamber 308. The load station 310 comprises a frame 502, a rail track 504, a conveyor tray 506 adapted to slide along the rail track 504 to convey substrates into and out of the loadlock chamber 308 via a slit valve 510, and a lid 511. In one embodiment, the conveyor tray 506 may be moved along the rail track 504 manually by the operator. In another embodiment, the conveyor tray 506 may be driven mechanically by a motor. In yet another embodiment, the conveyor tray 506 is moved along the rail track 504 by a pneumatic actuator.

Substrates for processing may be grouped in batches and transported on the conveyor tray 506. For example, each batch of substrates 514 may be transported on a carrier plate 512 that can be placed on the conveyor tray 506. The lid 511 may be selectively opened and closed over the conveyor tray 506 for safety protection when the conveyor tray 506 is driven in movement. In operation, an operator opens the lid 511 to load the carrier plate 512 containing a batch of substrates on the conveyor tray 506. A storage shelf 516 may be provided for storing carrier plates containing substrates to be loaded. The lid 511 is closed, and the conveyor tray 506 is moved through the slit valve 510 into the loadlock chamber 308. The lid 511 may comprise a glass material, such as Plexiglas or a plastic material to facilitate monitoring of operations of the conveyor tray 506.

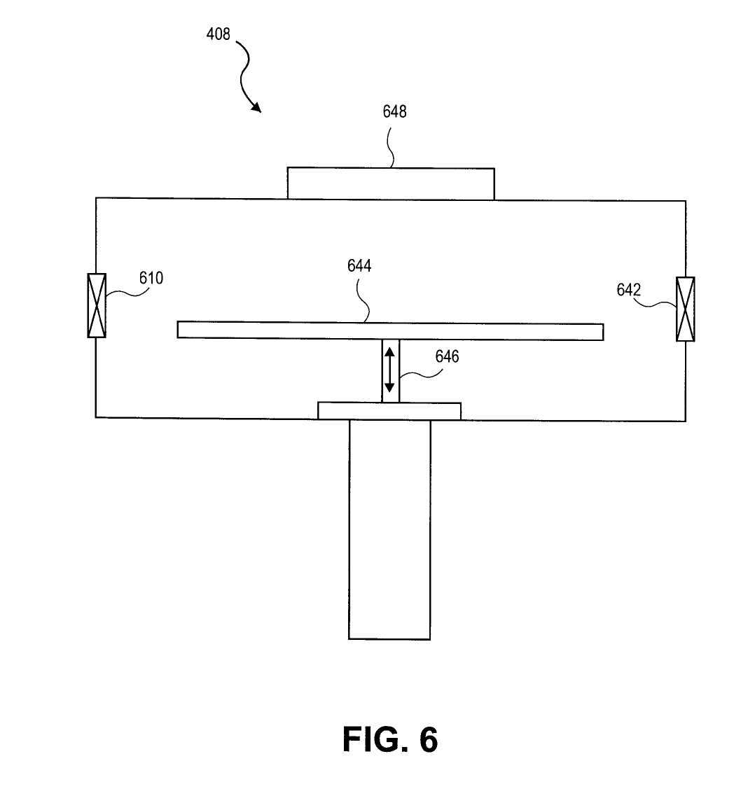

FIG. 6 is a schematic view of a loadlock chamber 308 according to an embodiment of the invention. The loadlock chamber 308 provides an interface between the atmospheric environment of the load station 310 and the controlled environment of the transfer chamber 306. Substrates are transferred between the loadlock chamber 308 and the load station 310 via the slit valve 510 and between the loadlock chamber 308 and the transfer chamber 306 via a slit valve 642. The loadlock chamber 308 comprises a carrier support 644 adapted to support incoming and outgoing carrier plates thereon. In one embodiment, the loadlock chamber 308 may comprise multiple carrier supports that are vertically stacked. To facilitate loading and unloading of a carrier plate, the carrier support 644 may be coupled to a stem 646 vertically movable to adjust the height of the carrier support 644. The loadlock chamber 308 is coupled to a pressure control system (not shown) which pumps down and vents the loadlock chamber 308 to facilitate passing the substrate between the vacuum environment of the transfer chamber 306 and the substantially ambient (e.g., atmospheric) environment of the load station 310. In addition, the loadlock chamber 308 may also comprise features for temperature control, such as a degas module 648 to heat substrates and remove moisture, or a cooling station (not shown) for cooling substrates during transfer. Once a carrier plate loaded with substrates has been conditioned in the loadlock chamber 308, the carrier plate may be transferred into the MOCVD chamber 302 or the HVPE chamber 304 for processing, or to the batch loadlock chamber 309 where multiple carrier plates are stored in standby for processing.

During operation, a carrier plate 512 containing a batch of substrates is loaded on the conveyor tray 506 in the load station 310. The conveyor tray 506 is then moved through the slit valve 510 into the loadlock chamber 308, placing the carrier plate 512 onto the carrier support 644 inside the loadlock chamber 308, and the conveyor tray returns to the load station 310. While the carrier plate 512 is inside the loadlock chamber 308, the loadlock chamber 308 is pumped and purged with an inert gas, such as nitrogen, in order to remove any remaining oxygen, water vapor, and other types of contaminants. After the batch of substrates have been conditioned in the loadlock chamber, the robot assembly 330 may transfer the carrier plate 512 to either the MOCVD chamber 302 or, the HVPE chamber 304 to undergo deposition processes. In alternate embodiments, the carrier plate 512 may be transferred and stored in the batch loadlock chamber 309 on standby for processing in either the MOCVD chamber 302 or the HVPE chamber 304. After processing of the batch of substrates is complete, the carrier plate 512 may be transferred to the loadlock chamber 308, and then retrieved by the conveyor tray 506 and returned to the load station 310.

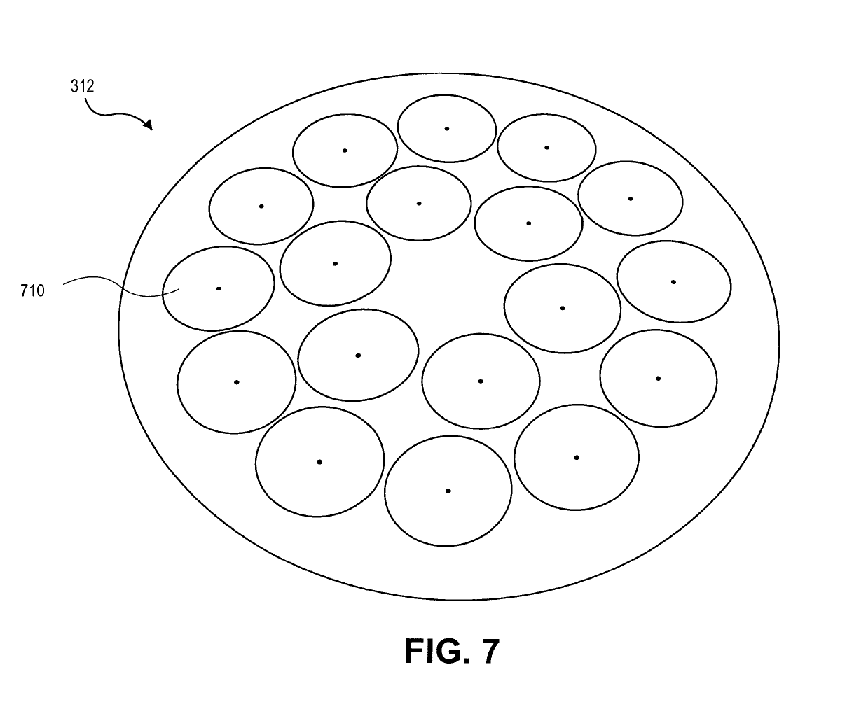

FIG. 7 is an isometric view of a carrier plate according to an embodiment of the invention. In one embodiment, the carrier plate 512 may include one or more circular recesses 710 within which individual substrates may be disposed during processing. The size of each recess 710 may be changed according to the size of the substrate to accommodate therein. In one embodiment, the carrier plate 512 may carry six or more substrates. In another embodiment, the carrier plate 512 carries eight substrates. In yet another embodiment, the carrier plate 512 carries 18 substrates. It is to be understood that more or less substrates may be carried on the carrier plate 512. Typical substrates may include sapphire, silicon carbide (SiC), silicon, or gallium nitride (GaN). It is to be understood that other types of substrates, such as glass substrates, may be processed. Substrate size may range from 50 mm-200 mm in diameter or larger. In one embodiment, each recess 710 may be sized to receive a circular substrate having a diameter between about 2 inches and about 6 inches. The diameter of the carrier plate 512 may range from 200 mm-750 mm, for example, about 300 mm. The carrier plate 512 may be formed from a variety of materials, including SiC, SiC-coated graphite, or other materials resistant to the processing environment. Substrates of other sizes may also be processed within the processing system 300 according to the processes described herein.

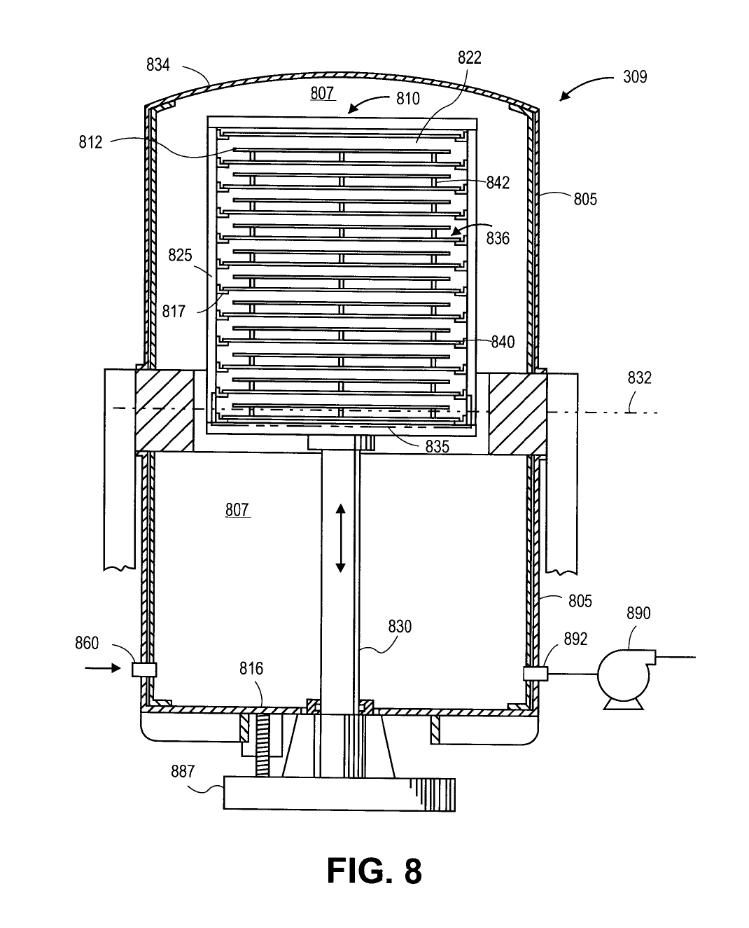

FIG. 8 is a schematic view of the batch loadlock chamber 309 according to an embodiment of the invention. The batch loadlock chamber 309 comprises a body 805 and a lid 834 and bottom 816 disposed on the body 805 and defining a cavity 807 for storing a plurality of substrates placed on the carrier plates 512 therein. In one aspect, the body 805 is formed of process resistant materials such as aluminum, steel, nickel, and the like, adapted to withstand process temperatures and is generally free of contaminates such as copper. The body 805 may comprise a gas inlet 860 extending into the cavity 807 for connecting the batch loadlock chamber 309 to a process gas supply (not shown) for delivery of processing gases therethrough. In another aspect, a vacuum pump 890 may be coupled to the cavity 807 through a vacuum port 892 to maintain a vacuum within the cavity 807.

A storage cassette 810 is moveably disposed within the cavity 807 and is coupled with an upper end of a movable member 830. The moveable member 830 is comprised of process resistant materials such as aluminum, steel, nickel, and the like, adapted to withstand process temperatures and generally free of contaminates such as copper. The movable member 830 enters the cavity 807 through the bottom 816. The movable member 830 is slidably and sealably disposed through the bottom 816 and is raised and lowered by the platform 887. The platform 887 supports a lower end of the movable member 830 such that the movable member 830 is vertically raised or lowered in conjunction with the raising or lowering of the platform 887. The movable member 830 vertically raises and lowers the storage cassette 810 within the cavity 807 to move the substrates carrier plates 512 across a substrate transfer plane 832 extending through a window 835. The substrate transfer plane 832 is defined by the path along which substrates are moved into and out of the storage cassette 810 by the robot assembly 330.

The storage cassette 810 comprises a plurality of storage shelves 836 supported by a frame 825. Although in one aspect, FIG. 8 illustrates twelve storage shelves 836 within storage cassette 810, it is contemplated that any number of shelves may be used. Each storage shelf 836 comprises a substrate support 840 connected by brackets 817 to the frame 825. The brackets 817 connect the edges of the substrate support 840 to the frame 825 and may be attached to both the frame 825 and substrate support 840 using adhesives such as pressure sensitive adhesives, ceramic bonding, glue, and the like, or fasteners such as screws, bolts, clips, and the like that are process resistant and are free of contaminates such as copper. The frame 825 and brackets 817 are comprised of process resistant materials such as ceramics, aluminum, steel, nickel, and the like that are process resistant and are generally free of contaminates such as copper. While the frame 825 and brackets 817 may be separate items, it is contemplated that the brackets 817 may be integral to the frame 825 to form support members for the substrate supports 840.

The storage shelves 836 are spaced vertically apart and parallel within the storage cassette 810 to define a plurality of storage spaces 822. Each substrate storage space 822 is adapted to store at least one carrier plate 512 therein supported on a plurality of support pins 842. The storage shelves 836 above and below each carrier plate 512 establish the upper and lower boundary of the storage space 822.

In another embodiment, substrate support 840 is not present and the carrier plates 512 rest on brackets 817.

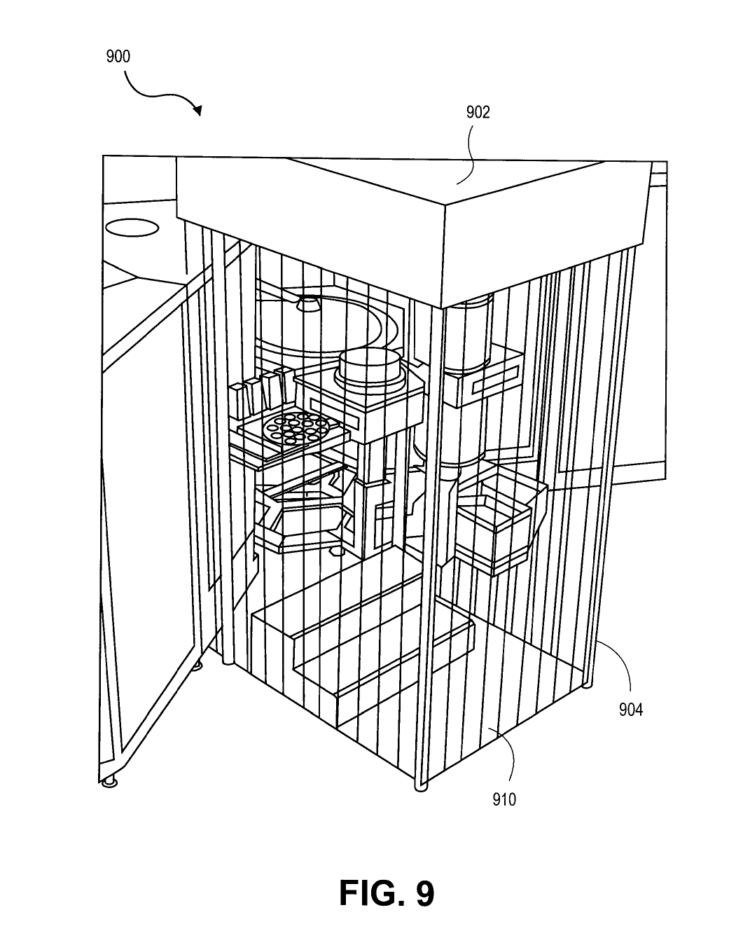

FIG. 9 is an isometric view of a work platform 900 according to one embodiment of the invention. In one embodiment, the processing system 300 further comprises a work platform 900 enclosing the load station 310. The work platform 900 provides a particle free environment during loading and unloading of substrates into the load station 310. The work platform 900 comprises a top portion 902 supported by four posts 904. A curtain 910 separates the environment inside the work platform 900 from the surrounding environment. In one embodiment, the curtain 910 comprises a vinyl material. In one embodiment the work platform comprises an air filter, such as a High Efficiency Particulate Air Filter (“HEPA”) filter for filtering airborne particles from the ambient inside the work platform. In one embodiment, air pressure within the enclosed work platform 900 is maintained at a slightly higher pressure than the atmosphere outside of the work platform 900 thus causing air to flow out of the work platform 900 rather than into the work platform 900.

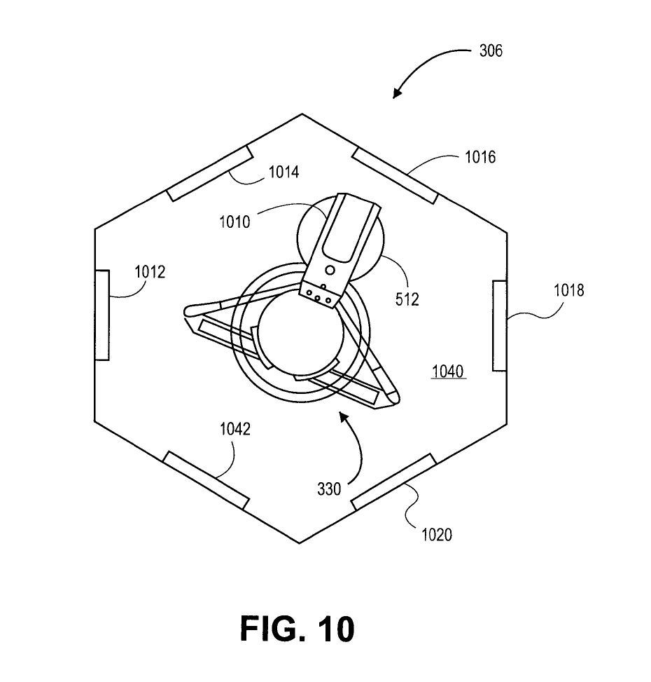

FIG. 10 is a plan view of a robot assembly 330 shown in the context of the transfer chamber 306. The internal region (e.g., transfer region 1040) of the transfer chamber 306 is typically maintained at a vacuum condition and provides an intermediate region in which to shuttle substrates from one chamber to another and/or to the loadlock chamber 308 and other chambers in communication with the cluster tool. The vacuum condition is typically achieved by use of one or more vacuum pumps (not shown), such as a conventional rough pump, Roots Blower, conventional turbo-pump, conventional cryo-pump, or combination thereof. Alternately, the internal region of the transfer chamber 306 may be an inert environment that is maintained at or near atmospheric pressure by continually delivering an inert gas to the internal region. Three such platforms are the Centura, the Endura and the Producer system all available from Applied Materials, Inc., of Santa Clara, Calif. The details of one such staged-vacuum substrate processing system are disclosed in U.S. Pat. No. 5,186,718, entitled “Staged-Vacuum Substrate Processing System and Method,” Tepman et al., issued on Feb. 16, 1993, which is incorporated herein by reference. The exact arrangement and combination of chambers may be altered for purposes of performing specific steps of a fabrication process.

The robot assembly 330 is centrally located within the transfer chamber 306 such that substrates can be transferred into and out of adjacent processing chambers, the loadlock chamber 308, and the batch loadlock chamber 309, and other chambers through slit valves 642, 1012, 1014, 1016, 1018, and 1020 respectively. The valves enable communication between the processing chambers, the loadlock chamber 308, the batch loadlock chamber 309, and the transfer chamber 306 while also providing vacuum isolation of the environments within each of the chambers to enable a staged vacuum within the system. The robot assembly 330 may comprise a frog-leg mechanism. In certain embodiments, the robot assembly 330 may comprise any variety of known mechanical mechanisms for effecting linear extension into and out of the various process chambers. A blade 1010 is coupled with the robot assembly 330. The blade 1010 is configured to transfer the carrier plate 512 through the processing systems. In one embodiment, the processing system 300 comprises an automatic center finder (not shown). The automatic center finder allows for the precise location of the carrier plate 512 on the robot assembly 330 to be determined and provided to a controller. Knowing the exact center of the carrier plate 512 allows the computer to adjust for the variable position of each carrier plate 512 on the blade and precisely position each carrier plate 512 in the processing chambers.

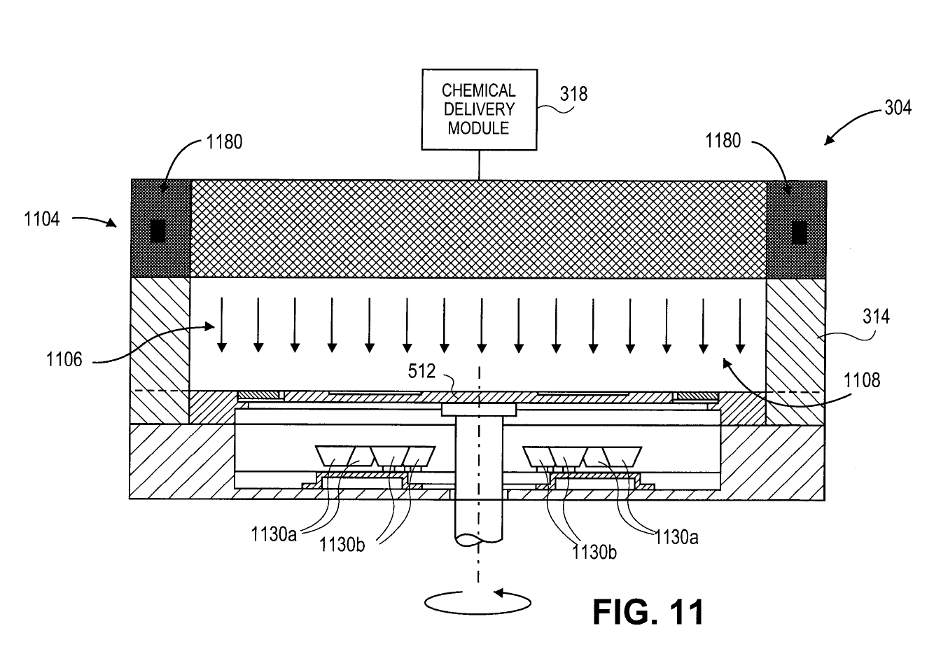

FIG. 11 is a schematic cross-sectional view of a HVPE chamber 304 according to an embodiment of the invention. The HVPE chamber 304 includes the chamber body 314 that encloses a processing volume 1108. A showerhead assembly 1104 is disposed at one end of the processing volume 1108, and the carrier plate 512 is disposed at the other end of the processing volume 1108. The showerhead assembly, as described above, may allow for more uniform deposition across a greater number of substrates or larger substrates than in traditional HVPE chambers, thereby reducing production costs. The showerhead may be coupled with a chemical delivery module 318. The carrier plate 512 may rotate about its central axis during processing. In one embodiment, the carrier plate 512 may be rotated at about 2 RPM to about 100 RPM. In another embodiment, the carrier plate 512 may be rotated at about 30 RPM. Rotating the carrier plate 512 aids in providing uniform exposure of the processing gases to each substrate.

A plurality of lamps 1130a, 1130b may be disposed below the carrier plate 512. For many applications, a typical lamp arrangement may comprise banks of lamps above (not shown) and below (as shown) the substrate. One embodiment may incorporate lamps from the sides. In certain embodiments, the lamps may be arranged in concentric circles. For example, the inner array of lamps 1130b may include eight lamps, and the outer array of lamps 1130a may include twelve lamps. In one embodiment of the invention, the lamps 1130a, 1130b are each individually powered. In another embodiment, arrays of lamps 1130a, 1130b may be positioned above or within showerhead assembly 1104. It is understood that other arrangements and other numbers of lamps are possible. The arrays of lamps 1130a, 1130b may be selectively powered to heat the inner and outer areas of the carrier plate 512. In one embodiment, the lamps 1130a, 1130b are collectively powered as inner and outer arrays in which the top and bottom arrays are either collectively powered or separately powered. In yet another embodiment, separate lamps or heating elements may be positioned over and/or under the source boat 1180. It is to be understood that the invention is not restricted to the use of arrays of lamps. Any suitable heating source may be utilized to ensure that the proper temperature is adequately applied to the processing chamber, substrates therein, and a metal source. For example, it is contemplated that a rapid thermal processing lamp system may be utilized such as is described in United States Patent Publication No. 2006/0018639, published Jan. 26, 2006, entitled PROCESSING MULTILAYER SEMICONDUCTORS WITH MULTIPLE HEAT SOURCES, which is incorporated by reference in its entirety.

In yet another embodiment, the source boat 1180 is remotely located with respect to the chamber body 314, as described in U.S. Provisional Patent Application Ser. No. 60/978,040, filed Oct. 5, 2007, titled METHOD FOR DEPOSITING GROUP III/V COMPOUNDS, which is incorporated by reference in its entirety.

One or more lamps 1130a, 1130b may be powered to heat the substrates as well as the source boat 1180. The lamps may heat the substrate to a temperature of about 900° C. to about 1200° C. In another embodiment, the lamps 1130a, 1130b maintain a metal source within the source boat 1180 at a temperature of about 350° C. to about 900° C. A thermocouple may be used to measure the metal source temperature during processing. The temperature measured by the thermocouple may be fed back to a controller that adjusts the heat provided from the heating lamps 1130a, 1130b so that the temperature of the metal source may be controlled or adjusted as necessary.

During the process according to one embodiment of the invention, precursor gases 1106 flow from the showerhead assembly 1104 towards the substrate surface. Reaction of the precursor gases 1106 at or near the substrate surface may deposit various metal nitride layers upon the substrate, including GaN, AlN, and InN. Multiple metals may also be utilized for the deposition of “combination films” such as AlGaN and/or InGaN. The processing volume 1108 may be maintained at a pressure of about 760 torr down to about 100 torr. In one embodiment, the processing volume 1108 is maintained at a pressure of about 450 torr to about 760 torr. Exemplary embodiments of the showerhead assembly 1104 and other aspects of the HVPE chamber are described in U.S. patent application Ser. No. 11/767,520, filed Jun. 24, 2007, entitled HVPE TUBE SHOWERHEAD DESIGN, which is herein incorporated by reference in its entirety. Exemplary embodiments of the HVPE chamber 304 are described in U.S. Patent Application Ser. No. 61/172,630 filed Apr. 24, 2009, entitled HVPE CHAMBER HARDWARE, which is herein incorporated by reference in its entirety.

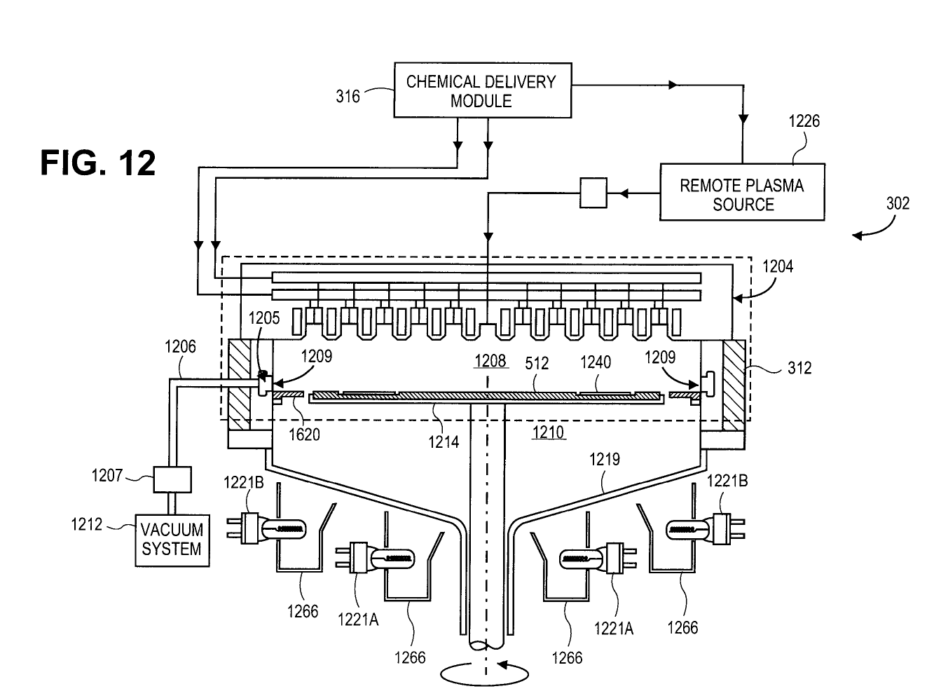

FIG. 12 is a schematic cross-sectional view of an MOCVD chamber according to an embodiment of the invention. The MOCVD chamber 302 comprises a chamber body 312, a chemical delivery module 316, a remote plasma source 1226, a substrate support 1214, and a vacuum system 1212. The chamber 302 includes a chamber body 312 that encloses a processing volume 1208. A showerhead assembly 1204 is disposed at one end of the processing volume 1208, and a carrier plate 512 is disposed at the other end of the processing volume 1208. The carrier plate 512 may be disposed on the substrate support 1214. Exemplary showerheads that may be adapted to practice the present invention are described in U.S. patent application Ser. No. 11/873,132, filed Oct. 16, 2007, entitled MULTI-GAS STRAIGHT CHANNEL SHOWERHEAD, U.S. patent application Ser. No. 11/873,141, filed Oct. 16, 2007, entitled MULTI-GAS SPIRAL CHANNEL SHOWERHEAD, and 11/873,170, filed Oct. 16, 2007, entitled MULTI-GAS CONCENTRIC INJECTION SHOWERHEAD, all of which are incorporated by reference in their entireties.

A lower dome 1219 is disposed at one end of a lower volume 1210, and the carrier plate 512 is disposed at the other end of the lower volume 1210. The carrier plate 512 is shown in process position, but may be moved to a lower position where, for example, the substrates 1240 may be loaded or unloaded. An exhaust ring 1220 may be disposed around the periphery of the carrier plate 512 to help prevent deposition from occurring in the lower volume 1210 and also help direct exhaust gases from the chamber 302 to exhaust ports 1209. The lower dome 1219 may be made of transparent material, such as high-purity quartz, to allow light to pass through for radiant heating of the substrates 1240. The radiant heating may be provided by a plurality of inner lamps 1221A and outer lamps 1221B disposed below the lower dome 1219 and reflectors 1266 may be used to help control the chamber 302 exposure to the radiant energy provided by inner and outer lamps 1221A, 1221B. Additional rings of lamps may also be used for finer temperature control of the substrates 1240.

A purge gas (e.g., nitrogen) may be delivered into the chamber 302 from the showerhead assembly 1204 and/or from inlet ports or tubes (not shown) disposed below the carrier plate 512 and near the bottom of the chamber body 312. The purge gas enters the lower volume 1210 of the chamber 302 and flows upwards past the carrier plate 512 and exhaust ring 1220 and into multiple exhaust ports 1209 which are disposed around an annular exhaust channel 1205. An exhaust conduit 1206 connects the annular exhaust channel 1205 to a vacuum system 1212 which includes a vacuum pump (not shown). The chamber 302 pressure may be controlled using a valve system 1207 which controls the rate at which the exhaust gases are drawn from the annular exhaust channel 1205. Other aspects of the MOCVD chamber are described in U.S. patent application Ser. No. 12/023,520, filed Jan. 31, 2008, (attorney docket no. 011977) entitled CVD APPARATUS, which is herein incorporated by reference in its entirety.

Various metrology devices, such as, for example, reflectance monitors, thermocouples, or other temperature devices may also be coupled with the chamber 302. The metrology devices may be used to measure various film properties, such as thickness, roughness, composition, temperature or other properties. These measurements may be used in an automated real-time feedback control loop to control process conditions such as deposition rate and the corresponding thickness. Other aspects of chamber metrology are described in U.S. Patent Application Ser. No. 61/025,252, filed Jan. 31, 2008, (attorney docket no. 011007) entitled CLOSED LOOP MOCVD DEPOSITION CONTROL, which is herein incorporated by reference in its entirety.

The chemical delivery modules 316, 318 supply chemicals to the MOCVD chamber 302 and HVPE chamber 304 respectively. Reactive and carrier gases are supplied from the chemical delivery system through supply lines into a gas mixing box where they are mixed together and delivered to respective showerheads 1204 and 1104. Generally supply lines for each of the gases include shut-off valves that can be used to automatically or manually shut-off the flow of the gas into its associated line, and mass flow controllers or other types of controllers that measure the flow of gas or liquid through the supply lines. Supply lines for each of the gases may also include concentration monitors for monitoring precursor concentrations and providing real time feedback, backpressure regulators may be included to control precursor gas concentrations, valve switching control may be used for quick and accurate valve switching capability, moisture sensors in the gas lines measure water levels and can provide feedback to the system software which in turn can provide warnings/alerts to operators. The gas lines may also be heated to prevent precursors and etchant gases from condensing in the supply lines. Depending upon the process used some of the sources may be liquid rather than gas. When liquid sources are used, the chemical delivery module includes a liquid injection system or other appropriate mechanism (e.g. a bubbler) to vaporize the liquid. Vapor from the liquids is then usually mixed with a carrier gas as would be understood by a person of skill in the art.

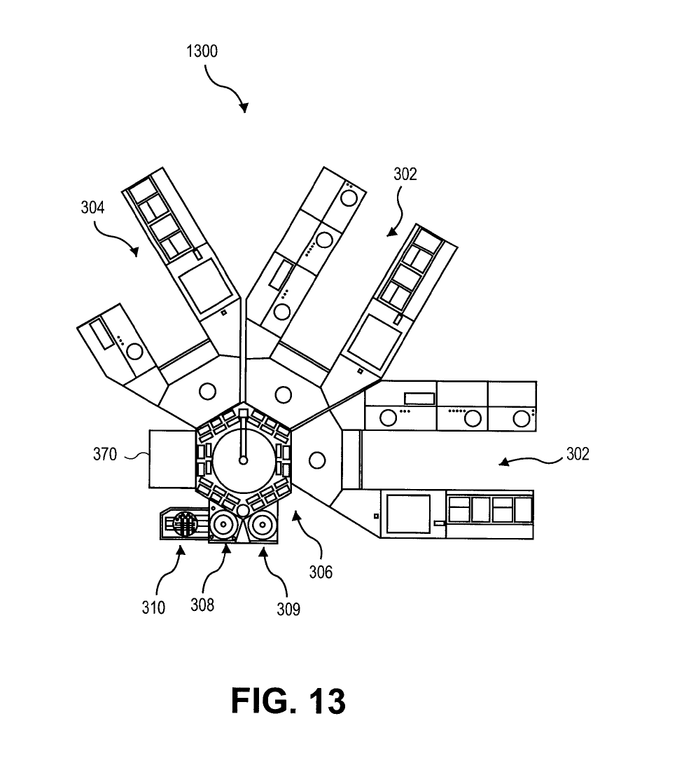

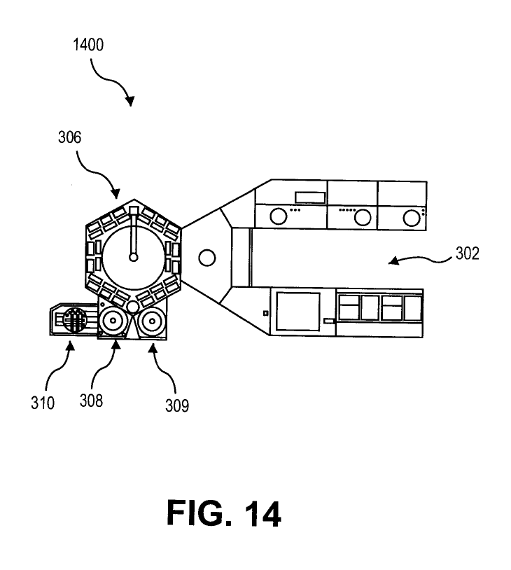

While the foregoing embodiments have been described in connection to a processing system that comprises one MOCVD chamber and one HVPE chamber, alternate embodiments may integrate one or more MOCVD and HVPE chambers in the processing system, as shown in FIGS. 13 and 14. FIG. 13 illustrates an embodiment of a processing system 1300 that comprises two MOCVD chambers 302 and one HVPE chamber 304 coupled to the transfer chamber 306. In the processing system 1300, the robot blade is operable to respectively transfer a carrier plate into each of the MOCVD chambers 302 and HVPE chamber 304. Multiple batches of substrates loaded on separate carrier plates thus can be processed in parallel in each of the MOCVD chambers 302 and HVPE chamber 304.

FIG. 14 illustrates a simpler embodiment of a processing system 1400 that comprises a single MOCVD chamber 302. In the processing system 1400, the robot blade transfers a carrier plate loaded with substrates into the single MOCVD chamber 302 to undergo deposition. After all the deposition steps have been completed, the carrier plate is transferred from the MOCVD chamber 302 back to the loadlock chamber 308, and then released toward the load station 310.

A system controller 360 controls activities and operating parameters of the processing system 300. The system controller 360 includes a computer processor and a computer-readable memory coupled to the processor. The processor executes system control software, such as a computer program stored in memory. Aspects of the processing system and methods of use are further described in U.S. patent application Ser. No. 11/404,516, filed Apr. 14, 2006, entitled EPITAXIAL GROWTH OF COMPOUND NITRIDE STRUCTURES, which is hereby incorporated by reference in its entirety.

The system controller 360 and related control software prioritize tasks and substrate movements based on inputs from the user and various sensors distributed throughout the processing system 300. The system controller 360 and related control software allow for automation of the scheduling/handling functions of the processing system 300 to provide the most efficient use of resources without the need for human intervention. In one aspect, the system controller 360 and related control software adjust the substrate transfer sequence through the processing system 300 based on a calculated optimized throughput or to work around processing chambers that have become inoperable. In another aspect, the scheduling/handling functions pertain to the sequence of processes required for the fabrication of compound nitride structures on substrates, especially for processes that occur in one or more processing chambers. In yet another aspect, the scheduling/handling functions pertain to efficient and automated processing of multiple batches of substrates, whereby a batch of substrates is contained on a carrier. In yet another aspect, the scheduling/handling functions pertain to periodic in-situ cleaning of processing chambers or other maintenance related processes. In yet another aspect, the scheduling/handling functions pertain to temporary storage of substrates in the batch loadlock chamber. In yet another aspect the scheduling/handling functions pertain to transfer of substrates to or from the load station based on operator inputs.

The following example is provided to illustrate how the general process described in connection with processing system 300 may be used for the fabrication of compound nitride structures. The example refers to a LED structure, with its fabrication being performed using a processing system 300 having at least two processing chambers, such as MOCVD chamber 302 and HVPE chamber 304. The cleaning and deposition of the initial GaN layers is performed in the HVPE chamber 304, with growth of the remaining InGaN, AlGaN, and GaN contact layers being performed in the MOCVD system 302.

The process begins with a carrier plate containing multiple substrates being transferred into the HVPE chamber 304. The HVPE chamber 304 is configured to provide rapid deposition of GaN. A pretreatment process and/or buffer layer is grown over the substrate in the HVPE chamber 304 using HVPE precursor gases. This is followed by growth of a thick n-GaN layer, which in this example is performed using HVPE precursor gases. In another embodiment the pretreatment process and/or buffer layer is grown in the MOCVD chamber and the thick n-GaN layer is grown in the HVPE chamber.

After deposition of the n-GaN layer, the substrate is transferred out of the HVPE chamber 304 and into the MOCVD chamber 302, with the transfer taking place in a high-purity N₂ atmosphere via the transfer chamber 306. The MOCVD chamber 302 is adapted to provide highly uniform deposition, perhaps at the expense of overall deposition rate. In the MOCVD chamber 302, the InGaN multi-quantum-well active layer is grown after deposition of a transition GaN layer. This is followed by deposition of the p-AlGaN layer and p-GaN layer. In another embodiment the p-GaN layer is grown in the HVPE chamber.

The completed structure is then transferred out of the MOCVD chamber 302 so that the MOCVD chamber 302 is ready to receive an additional carrier plate containing partially processed substrates from the HVPE chamber 304 or from a different processing chamber. The completed structure may either be transferred to the batch loadlock chamber 309 for storage or may exit the processing system 300 via the loadlock chamber 308 and the load station 310.

Before receiving additional substrates the HVPE chamber and/or MOCVD chamber may be cleaned via an in-situ clean process. The cleaning process may comprise etchant gases which thermally etch deposition from chamber walls and surfaces. In another embodiment, the cleaning process comprises a plasma generated by a remote plasma generator. Exemplary cleaning processes are described in U.S. patent application Ser. No. 11/404,516, filed on Apr. 14, 2006, and U.S. patent application Ser. No. 11/767,520, filed on Jun. 24, 2007, titled HVPE SHOWERHEAD DESIGN, both of which are incorporated by reference in their entireties.

An improved system and method for fabricating compound nitride semiconductor devices has been provided. In conventional manufacturing of compound nitride semiconductor structures, multiple epitaxial deposition steps are performed in a single process reactor, with the substrate not leaving the process reactor until all of the steps have been completed resulting in a long processing time, usually on the order of 4-6 hours. Conventional systems also require that the reactor be manually opened in order to remove and insert additional substrates. After opening the reactor, in many cases, an additional 4 hours of pumping, purging, cleaning, opening, and loading must be performed resulting in a total run time of about 8-10 hours per substrate. The conventional single reactor approach also prevents optimization of the reactor for individual process steps.

The improved system provides for simultaneously processing substrates using a multi-chamber processing system that has an increased system throughput, increased system reliability, and increased substrate to substrate uniformity. The multi-chamber processing system expands the available process window for different compound structures by performing epitaxial growth of different compounds in different processing having structures adapted to enhance those specific procedures. Since the transfer of substrates is automated and performed in a controlled environment, this eliminates the need for opening the reactor and performing a long pumping, purging, cleaning, opening, and loading process.

Thus, a method of reducing the degradation of multi quantum well (MQW) light emitting diodes has been described.

We claim:

1. A method of fabricating a light emitting diode comprising:
forming a active region over a substrate wherein the active region comprises a plurality of gallium nitride (GaN) barrier layers and a plurality of indium gallium nitride (InGaN) quantum well layers; and
forming a p-type gallium nitride layer by hydride vapor phase epitaxy (HVPE) above the active region at a high deposition rate.

2. The method of claim 1 wherein said high deposition rate is greater than 25 μm/hr.

3. The method of claim 1 further comprising heating said substrate to a temperature less than 900° C. while depositing said p-type gallium nitride layer by HVPE.

4. The method of claim 1 wherein said p-type gallium nitride layer is doped with magnesium.

5. The method of claim 1 further comprising forming a p-type electron blocking layer between said p-type gallium nitride layer and said active region.

6. The method of claim 1 wherein said p-type electron blocking layer is formed by an HVPE process at a high growth rate of greater than 25 μm/hr.

7. The method of claim 1 wherein said barrier layers and said quantum well layers are formed by MOCVD.

8. The method of claim 1 wherein said active region is formed in one or more MOCVD chambers of a cluster tool and wherein said p-type GaN layer is formed in a HVPE chamber of said cluster tool.
